(19) United States
(12) Patent Application Publication
(10) Pub. No.: US 2003/0067320 A1
(43) Pub. Date: Apr. 10, 2003

(54) Transmission line system

(76) Inventors: Andre Schafer, Munchen (DE); Andrea Zuckerstatter, Munchen (DE)

Correspondence Address: LERNER AND GREENBERG, P.A., Post Office Box 2480, Hollywood, FL, 33022-2480, US

(21) Appl. No.: 10/266,186

(22) Filed: Oct. 7, 2002

(30) Foreign Application Priority Data
Oct. 5, 2001 (DE) 101 49 032.1

(51) Int. Cl. H03K 17/16; H01P 1/26

(52) U.S. Cl. 326/30; 333/22 R

(57) ABSTRACT

A transmission line system for transmitting signals to a means operating at a predetermined clock frequency includes a driver circuit and a transmission line, which comprises an associated terminating impedance. The length of the transmission line and/or the associated terminating impedance is set such that the so established resonance frequency is lower than the predetermined clock frequency.

### BACKGOUND OF THE INVENTION

1. Field of the Invention

The present invention relates to a transmission line system, in particular to a transmission line system for transmitting signals to a means operating at a predetermined clock frequency, and here, in particular, to a transmission line system for reducing the power consumption of clock driver circuits which are connected to the transmission line system.

2. Description of the Related Art

The prior art knows transmission systems or bus systems working at high speeds. A disadvantage in these known high speed systems is that the energy converted in the clock driver circuits negatively affects the reliability of the clock element. In order to eliminate this disadvantage, it is, therefore, necessary to minimize or to reduce the power consumption in the clock element and/or in the clock generator.

One possibility for solving this problem, which is known in the state of the art, is to minimize the energy consumed in the clock generator by reducing the voltage swing. This procedure, however, requires a termination to be provided at the receiver, i. e. at end of the transmission line, with this termination, in turn, consuming energy such that, also with this known method, the power consumption of the total system is practically not decreased.

Starting from this state of the art, the present invention is based on the object of providing an enhanced transmission line system for high speed applications, which enables the power consumption in the associated driver circuit to be minimized or reduced.

### SUMMERY OF THE INVENTION

The present invention is a transmission line system for transmitting signals to a means, which operates at a predetermined clock frequency, having

a driver circuit; and

a transmission line with an associated terminating impedance, wherein a length of the transmission line and/or the associated terminating impedance is set such that the so established resonance frequency is lower than the predetermined clock frequency.

The present invention is based on the recognition, that, in clock bus systems, which have no or a “high-resistance” terminating impedance, there exists a resonance frequency, starting from which the power consumed in the clock driver circuit drops again. Here, the resonance frequency of the clock bus system is a function of the line length of the busses and/or of the terminating impedance (complex termination resistance). In accordance with the present invention it was recognized that, by an appropriate selection of the bus line lengths and/or terminating impedance such that the bus resonance frequency is below the clock frequency of the application, the power consumed in the driver circuit may be significantly reduced.

In accordance with a preferred embodiment of the present invention, the inventive system includes a plurality of transmission lines, in which the lengths and/or terminating impedances are each adjusted such that a so set resonance frequency of the associated transmission line is lower than the predetermined clock frequency of the application which connects to the transmission lines.

In accordance with a preferred embodiment, the terminating impedance includes a resistor and/or a capacitive element, which is connected between the output of the transmission line and the ground.

### BRIEF DESCRIBTION OF THE DRAWINGS

Preferred embodiments of the present invention are described in detail below with reference to the attached drawings, in which:

FIG. 1 shows an exemplary clock bus system;

FIG. 2A shows an example for a push-pull clock driver circuit;

FIG. 2B shows an equivalent circuit diagram of the driver circuit from FIG. 2A; and

FIG. 3 shows a diagram of the power consumption in the resistors of the driver circuit above the clock frequency.

### DESCRIPTION OF THE PREFERED EMBODIMENTS

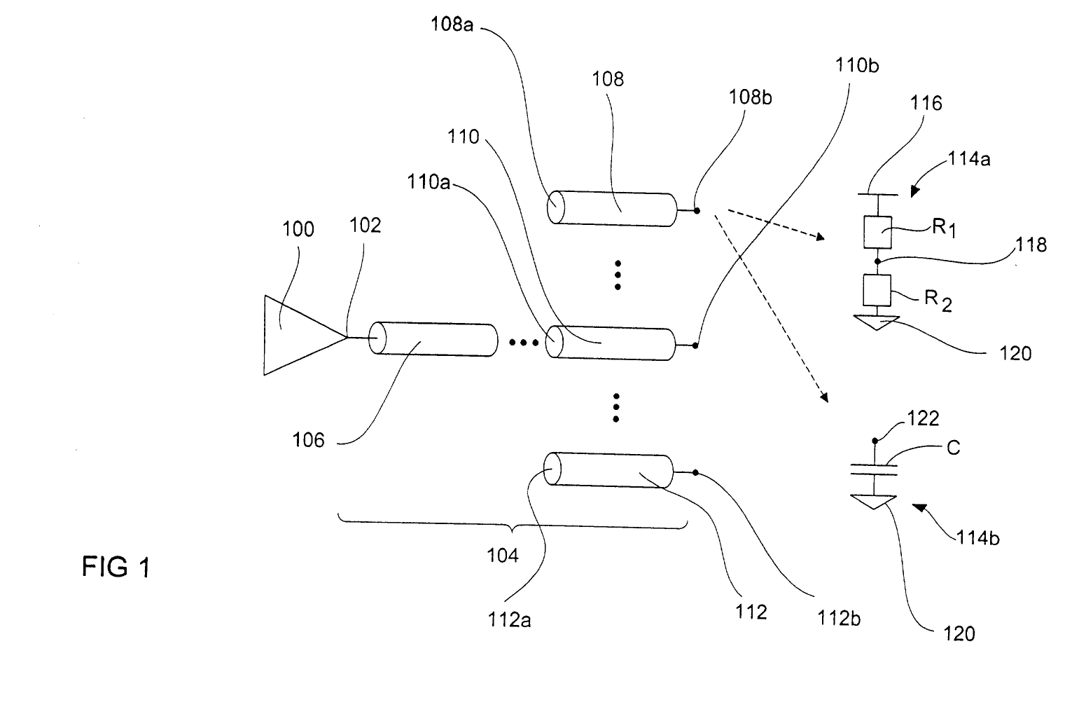

FIG. 1 shows an example for a high-speed clock bus system, wherein the term “high speed” stands for clock frequencies in the range of about 200 MHz and upwards.

FIG. 1 shows a driver circuit 100, the output 102 of which is connected to the input of a clock bus system, which, in its entirety, is designated by the reference number 104. In accordance with the illustrated embodiment, the exemplary bus system 104 includes a first transmission line section 106 as well as a second transmission line section 108, a third transmission line section 110, and a fourth transmission line section 112. The transmission line sections 108, 110, and 112 preferably have the same characteristic impedance Z as the transmission line section 106. The length of the transmission line results from the compound length of the respective transmission line sections 106 and 108, 106 and 110, 106 and 112.

The first transmission line section 106 is connected between the output 102 of the driver circuit 100 and the inputs 108a, 107a, and 112a of the transmission line sections 108, 110, and 112. The transmission line sections 108 to 112 each include outputs 108b, 110b, and 112b, via which the transmission line sections 108 to 112 are connected to applications, which operate at a predetermined clock frequency. Examples for such applications are e.g. DRAMs.

Further, terminating impedances 114a or 114b are provided at the outputs 108b to 112b of the transmission line sections 108 to 112. The terminating impedance 114a is a so-called “light” termination, meaning that the arriving signal will be reflected for the most part.

The terminating impedance 114a includes two resistors R₁ and R₂, which are connected in series. The resistor R₁ is connected between a potential 116, preferably a supply voltage, and a node 118. The second resistor R₂ is connected between the node 118 and a second potential, e.g. the ground. If the output impedance 114a is employed at the output of the transmission line sections 108 to 112, the output 108b to 112b of the respective transmission line section is connected to the node 118. For the resistors R₁ and R₂, the following applies:

R₁>3·Z (1)

R₂>3·Z (2)

where:

Z=characteristic impedance of the transmission lines in the bus system 104.

The characteristic impedance of the transmission line sections of the bus system 104 is for example 50 Ω, and the resistance of the resistors R₁ and R₂ is preferably 150 Ω.

The second output impedance 114b includes a capacitive device C, which is connected between a node 122 and a potential 120, e.g. the ground. Upon termination to one of the transmission line sections, the node 122 is connected to the associated output of the transmission line section. The capacitive coupling, which is illustrated by the element C in FIG. 1, in reality, may in reality e.g. be achieved by omitting a termination at the output such that the natural capacity appears between the output termination of the transmission lines and the ground.

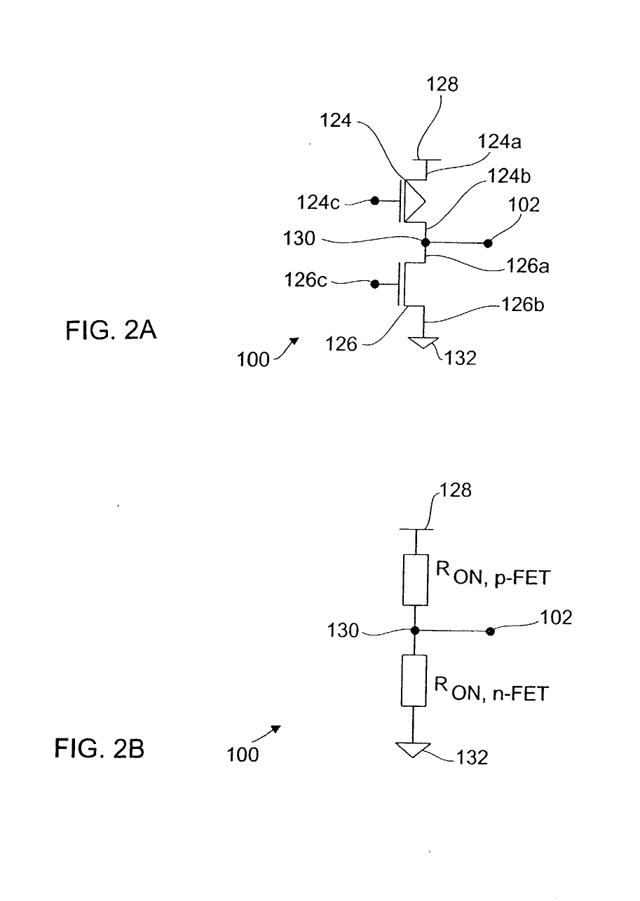

Using FIG. 2A, an embodiment for a possible implementation of the driver circuit 100 from FIG. 1 will be discussed, wherein the embodiment shown in FIG. 2A shows a push-pull driver. The driver circuit 100 in FIG. 2A includes a p-field effect transistor (p-FET) 124 including a first terminal 124a, a second terminal 124b as well as a control terminal 124c. Further, the driver circuit 100 includes an n-field effect transistor 126 (n-FET) including a first terminal 126a, a second terminal 126b as well as control terminal 126c. The first p-FET 124 is connected between a first potential 128 and a node 130 such that the first terminal 124a of the p-FET 124 is connected to the first potential 128 and that the second terminal 124b of the p-FET 124 is connected to the node 130. The n-FET 126 is connected between the node 130 and a second potential, e.g. ground 132, such that its first terminal 126a is connected to the node 130 and that its second terminal 126b is connected to the second potential 132. The node 130 is connected to the output 102 of the driver circuit 100.

In FIG. 2B, an equivalent circuit diagram of the driver circuit described in FIG. 2A is shown, with the equivalent circuit diagram comprising a resistor arrangement, which models the power-on range of the p-FET 124 and of the p-FET 126 by a linear resistor. Further, the power of the clock driver circuit is converted in these resistors.

As can be gathered from FIG. 2B, the p-FET 124 from FIG. 2A is illustrated by the resistor R_{on,p-FET}, which is connected between the first potential 128 and the node 130. The n-FET 126 is illustrated by the resistor R_{on,n-FET}, which is connected between the node 130 and the potential 132.

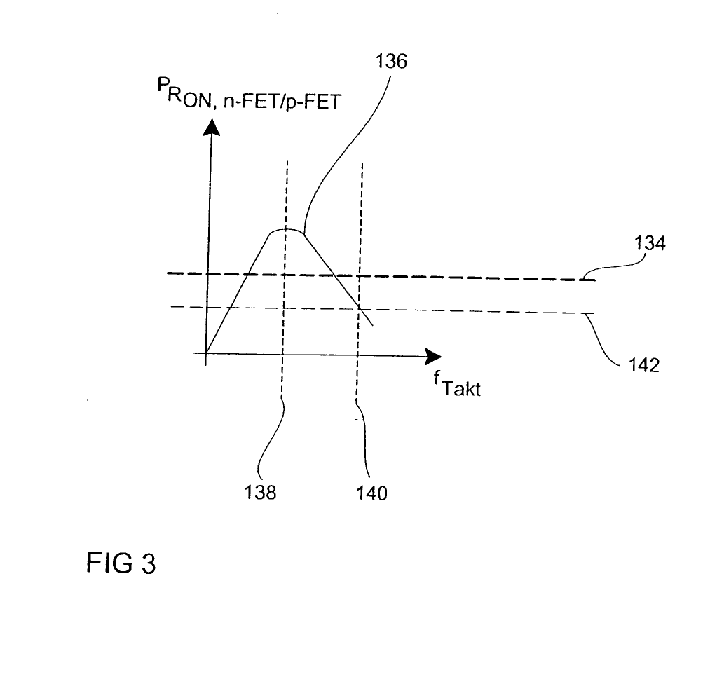

FIG. 3 shows a graph, which, for the push-pull equivalent circuit diagram from FIG. 2B, illustrates the energy expenditure in the two resistors versus the clock frequency in a fixed clock bus topology. In FIG. 3, the clock frequency f_{clock} is plotted along the X-axis, and, along the Y-axis, the power consumed in the resistors shown in FIG. 2B is illustrated. The dotted line 134 in FIG. 3 illustrates the limit for the critical power for the clock generator, i.e. that power, which, when exceeded, is expected to create some problems with respect to the reliability of the clock generator, e.g. due to heat development or similar. The curve 136 shows the course of the power P, which is converted in the resistors of the driver circuit, above the clock frequency f_{clock} in a steady bus topology. The line 138 designates the area of the resonance frequency of the bus system, and the line 140 designates the clock frequency, at which the application connected to the bus system operates. As can be seen from FIG. 3, the converted power or converted energy exhibits an essentially linear increase with the clock frequency f_{clock} in the area before the resonance frequency 138 of the bus system. In the area of the resonance frequency 138, the converted energy reaches a maximum and, for a large area around the resonance frequency, ranges already above the critical power for the clock generator. After reaching the resonance frequency 138, the converted power drops down again to a minimum in order to rise again (not shown).

The resonance frequency of the clock bus system, as described for example by FIG. 1, is a function of the line topology and here, in particular, of the line length and/or of the terminating impedance. By means of these two parameters (line length and/or terminating impedance), it is possible to adjust the resonance frequency of the bus system to a desired value. If a clock frequency of the application, which is connected to the bus system, is known, the effect of the dropping of the converted energy after reaching the resonance frequency of the bus system, which is described by means of FIG. 3, may now be utilized to change the parameters of the bus systems such that the clock frequency of the application ranges above the resonance frequency of the bus system such that, during the operation of the bus system at the clock frequency of the application, a significantly lower power is converted as is made clear by line 142.

In other words, the present invention enables the power converted in the driver circuit to be reduced in a straightforward manner with the topology of the bus system 104 being selected such by setting the line length and/or the terminating impedance that a resonance frequency resulting from this setting ranges below the clock frequency of the application, which is connected to the bus system, such that a drop in the energy converted in the driver 100 may be achieved, which surely ranges below the critical power for the clock generator and, thus, surely avoids the prior art problems connected to the increased power conversion.

List of Reference Numbers:

| | |
|---|---|
| 100 | driver circuit |
| 102 | output of the driver circuit |
| 104 | bus system |
| 106 | first transmission line section |
| 108 | second transmission line section |
| 108a | input of the second transmission line section |
| 108b | output of the second transmission line section |
| 110 | third transmission line section |
| 110a | input of the third transmission line section |
| 110b | output of the third transmission line section |
| 112 | fourth transmission line section |
| 112a | input of the fourth transmission line section |
| 112b | output of the fourth transmission line section |
| 114a, 114b | terminating impedance |
| 116 | potential |
| 118 | node |
| 120 | ground |
| 122 | node |
| 124 | p-field effect transistor |
| 124a | first termination of the p-field effect transistor |
| 124b | second termination of the p-field effect transistor |
| 124c | control termination of the p-field effect transistor |
| 126 | n-field effect transistor |
| 126a | first termination of the n-field effect transistor |
| 126b | second termination of the n-field effect transistor |
| 126c | control termination of the n-field effect transistor |
| 128 | potential |
| 130 | node |
| 132 | ground |
| 134 | line |
| 136 | curve |
| 138 | resonance frequency of the bus system |
| 140 | clock frequency |
| 142 | line |
| R₁, R₂ | resistor |
| C | capacitive element |

What is claimed i

1. A transmission line system for transmitting signals to a means operating at a predetermined clock frequency, comprising
a driver circuit; and
a transmission line having an associated terminating impedance, wherein a length of the transmission line and/or the associated terminating impedance is set such that the so established resonance frequency is lower than the predetermined clock frequency.

2. A transmission line system in accordance with claim 1, having a plurality of transmission lines, wherein each of the transmission lines comprises an associated terminating impedance, wherein the length of each transmission line and/or the associated terminating impedance s set such that the so established resonance frequency of each transmission line is lower than the predetermined clock frequency.

3. A transmission line in accordance with claim 1, wherein the terminating impedance includes a resistor and/or a capacitive element (C), wherein the terminating impedance is connected between an output of the transmission line and ground.

4. A transmission line system in accordance with claim 3, wherein the resistance value of the terminating impedance fulfills the following equation:
R>3·z
where:
R=resistance value
Z=characteristic impedance of the transmission lines.

5. A transmission line in accordance with claims 1, wherein the driver circuit includes a series circuit consisting of two field effect transistors.
